(19) United States
(12) Patent Application Publication
(10) Pub. No.: US 2025/0015111 A1
(43) Pub. Date: Jan. 9, 2025

(54) DETECTION DEVICE

(71) Applicant: Japan Display Inc., Tokyo (JP)

(72) Inventors: Yoshitaka OZEKI, Tokyo (JP); Takahiro TAKEUCHI, Tokyo (JP)

(21) Appl. No.: 18/761,679

(22) Filed: Jul. 2, 2024

(30) Foreign Application Priority Data
Jul. 4, 2023 (JP) 2023-109950

(51) Int. Cl. H01L 27/146; G06V 40/13; H04N 25/76

(52) U.S. Cl. CPC H01L 27/14627; H01L 27/14621; H01L 27/14623; H01L 27/14643; G06V 40/1318; H04N 25/76

(57) ABSTRACT

A detection device includes a substrate, a photodiode provided on the substrate, a lens provided so as to overlap the photodiode, a light-blocking layer that is provided between the photodiode and the lens, and is provided with an opening in a region overlapping the photodiode, and a light-transmitting resin layer and a buffer layer that are stacked between the light-blocking layer and the lens. The lens is provided in direct contact with a top of the buffer layer.

### CROSS-REFERENCE TO RELATED APPLICATION

This application claims the benefit of priority from Japanese Patent Application No. 2023-109950 filed on Jul. 4, 2023, the entire contents of which are incorporated herein by reference.

### BACKGROUND

### 1. Technical Field

The present disclosure relates to a detection device.

### 2. Description of the Related Art

Japanese Patent Application Laid-open Publication No. 2022-084273 describes a detection device including a plurality of photodiodes, a light-transmitting resin layer covering the photodiodes, and a plurality of lenses provided so as to overlap each of the photodiodes. The lenses are provided directly on top of the light-transmitting resin layer.

In such a detection device, if variations occur in shape of the lenses, the state of light focused on the photodiodes through the lenses varies, which may reduce detection accuracy. Therefore, the variations in shape of the lenses are required to be reduced in the detection device.

### SUMMARY

A detection device according to an embodiment of the present disclosure includes a substrate, a photodiode provided on the substrate, a lens provided so as to overlap the photodiode, a light-blocking layer that is provided between the photodiode and the lens, and is provided with an opening in a region overlapping the photodiode, and a light-transmitting resin layer and a buffer layer that are stacked between the light-blocking layer and the lens. The lens is provided in direct contact with a top of the buffer layer.

### BRIEF DESCRIPTION OF THE DRAWINGS

FIG. 1A is a sectional view illustrating a schematic sectional configuration of a detection device according to an embodiment of the present disclosure;

FIG. 1B is a sectional view illustrating a schematic sectional configuration of the detection device according to a first modification;

FIG. 1C is a sectional view illustrating a schematic sectional configuration of the detection device according to a second modification;

FIG. 1D is a sectional view illustrating a schematic sectional configuration of the detection device according to a third modification;

FIG. 2 is a plan view illustrating the detection device according to the embodiment;

FIG. 3 is a block diagram illustrating a configuration example of the detection device according to the embodiment;

FIG. 4 is a circuit diagram illustrating a detection element;

FIG. 5 is a plan view illustrating an optical filter according to the embodiment;

FIG. 6 is a sectional view along VI-VI′ of FIG. 5;

FIG. 7 is an explanatory view schematically illustrating a sectional configuration of a lens according to an example;

FIG. 8 is an explanatory view schematically illustrating a sectional configuration of the lens according to a comparative example;

FIG. 9 is a table illustrating measurement results of the lens according to the example and the lens structure according to the comparative example;

FIG. 10 is a plan view schematically illustrating a photodiode of the detection device according to the embodiment; and

FIG. 11 is a sectional view along XI-XI′ of FIG. 10.

### DETAILED DESCRIPTION

The following describes a mode (embodiment) for carrying out the present disclosure in detail with reference to the drawings. The present disclosure is not limited to the description of the embodiment to be given below. Components to be described below include those easily conceivable by those skilled in the art or those substantially identical thereto. In addition, the components to be described below can be combined as appropriate. What is disclosed herein is merely an example, and the present disclosure naturally encompasses appropriate modifications easily conceivable by those skilled in the art while maintaining the gist of the present disclosure. To further clarify the description, the drawings may schematically illustrate, for example, widths, thicknesses, and shapes of various parts as compared with actual aspects thereof. However, they are merely examples, and interpretation of the present disclosure is not limited thereto. The same component as that described with reference to an already mentioned drawing is denoted by the same reference numeral through the present disclosure and the drawings, and detailed description thereof may not be repeated where appropriate.

In the present specification and claims, in expressing an aspect of disposing another structure above a certain structure, a case of simply expressing “above” includes both a case of disposing the other structure immediately above the certain structure so as to contact the certain structure and a case of disposing the other structure above the certain structure with still another structure interposed therebetween, unless otherwise specified.

### Embodiment

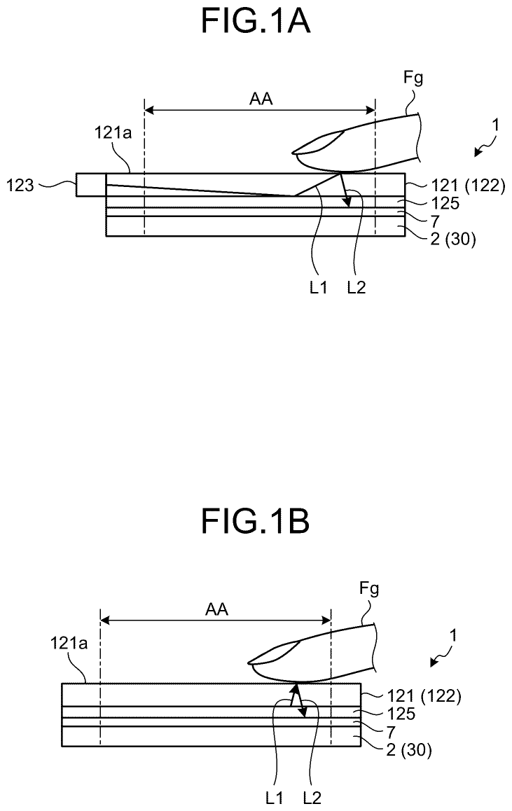

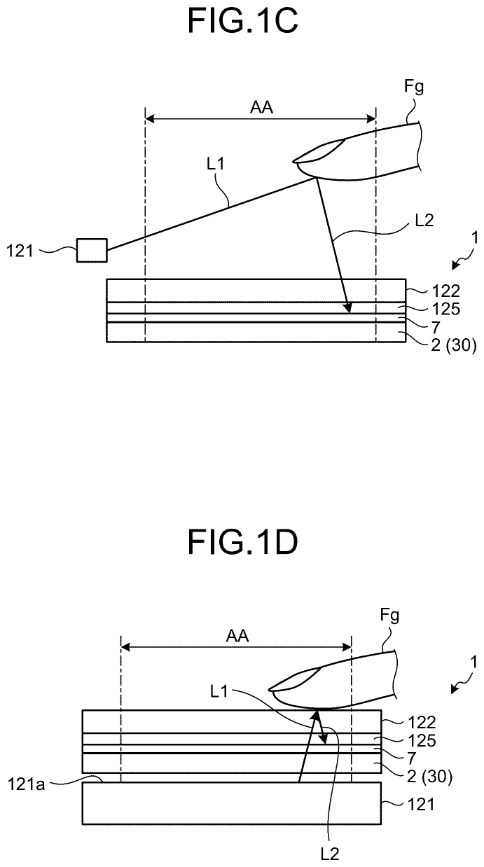

FIG. 1A is a sectional view illustrating a schematic sectional configuration of a detection device according to an embodiment of the present disclosure. FIG. 1B is a sectional view illustrating a schematic sectional configuration of the detection device according to a first modification. FIG. 1C is a sectional view illustrating a schematic sectional configuration of the detection device according to a second modification. FIG. 1D is a sectional view illustrating a schematic sectional configuration of the detection device according to a third modification.

As illustrated in FIG. 1A, a detection device 1 includes an array substrate 2 (photodiode 30), an optical filter 7, an adhesive layer 125, and an illumination device 121 (cover member 122). That is, the array substrate 2 (photodiode 30), the optical filter 7, the adhesive layer 125, and the cover member 122 are stacked in this order in a direction orthogonal to a surface of the array substrate 2. As will be described later, the cover member 122 may be replaced with the illumination device 121. The adhesive layer 125 only needs to bond the optical filter 7 to the cover member 122, and the detection device 1 may have a structure without the adhesive layer 125 in a region corresponding to a detection region AA. When the adhesive layer 125 is absent in the detection region AA, the detection device 1 has a structure in which the adhesive layer 125 bonds the cover member 122 to the optical filter 7 in a region corresponding to a peripheral region GA outside the detection region AA. The adhesive layer 125 provided in the detection region AA may be simply paraphrased as a protective layer for the optical filter 7.

As illustrated in FIG. 1A, the lighting device 121 may be a so-called side-light type front light, for example, using the cover member 122 as a light guide plate provided at a position corresponding to the detection region AA of the detection device 1 and having a plurality of light sources 123 lined up at one or both ends of the cover member 122. That is, the cover member 122 has a light-emitting surface 121a for emitting light, and serves as one component of the illumination device 121. The illumination device 121 emits light L1 from the light-emitting surface 121a of the cover member 122 toward a finger Fg that serves as a detection target. For example, light-emitting diodes (LEDs) that emit light in a predetermined color are used as the light sources 123.

As illustrated in FIG. 1B, the illumination device 121 may include the light sources (for example, LEDs) provided directly below the detection region AA of the detection device 1. The illumination device 121 including the light sources also serves as the cover member 122.

The illumination device 121 is not limited to the example of FIG. 1B. As illustrated in FIG. 1C, the illumination device 121 may be provided on a lateral side or an upper side of the cover member 122, and may emit the light L1 to the finger Fg from the lateral side or the upper side of the finger Fg.

Furthermore, as illustrated in FIG. 1D, the illumination device 121 may be what is called a direct-type backlight that includes the light sources (for example, LEDs) provided in the detection region AA of the detection device 1.

The light L1 emitted from the illumination device 121 is reflected as light L2 by the finger Fg serving as the detection target. The detection device 1 detects the light L2 reflected by the finger Fg to detect asperities (such as a fingerprint) on a surface of the finger Fg. The detection device 1 may further detect information on a living body by detecting the light L2 reflected in the finger Fg, in addition to detecting the fingerprint. Examples of the information on the living body include a vascular image, pulsation, and pulse waves of, for example, veins. The color of the light L1 from the illumination device 121 may be changed depending on the detection target.

The cover member 122 is a member for protecting the array substrate 2 and the optical filter 7, and covers the array substrate 2 and the optical filter 7. The illumination device 121 may have a structure to double as the cover member 122, as described above. In the structures illustrated in FIGS. 1C and 1D in which the cover member 122 is separate from the illumination device 121, the cover member 122 is a glass substrate, for example. The cover member 122 is not limited to the glass substrate, but may be a resin substrate, for example. The cover member 122 need not be provided. In that case, the surface of the array substrate 2 and the optical filter 7 is provided with a protective layer of, for example, an insulating film, and the finger Fg contacts the protective layer of the detection device 1.

In FIG. 1B, a display panel may be provided instead of the illumination device 121. The display panel may be, for example, an organic electroluminescent (EL) (organic light-emitting diode (OLED)) display panel or an inorganic EL (micro-LED or mini-LED) display. Alternatively, the display panel may be a liquid crystal display (LCD) panel using liquid crystal elements as display elements or an electrophoretic display (EPD) panel using electrophoretic elements as display elements. Also in this case, the fingerprint of the finger Fg and the information on the living body can be detected based on the light L2 obtained by reflecting display light (light L1) emitted from the display panel by the finger Fg.

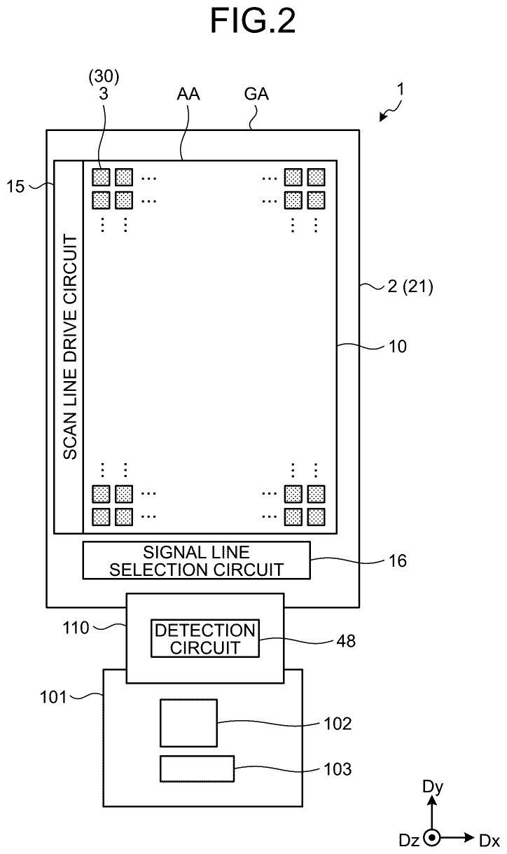

FIG. 2 is a plan view illustrating the detection device according to the embodiment. A first direction Dx illustrated in FIG. 2 and the subsequent drawings is one direction in a plane parallel to a substrate 21. A second direction Dy is one direction in the plane parallel to the substrate 21, and is a direction orthogonal to the first direction Dx. The second direction Dy may non-orthogonally intersect the first direction Dx. A third direction Dz is a direction orthogonal to the first direction Dx and the second direction Dy, and is a direction normal to the substrate 21. The term “plan view” refers to a positional relation as viewed from the third direction Dz.

As illustrated in FIG. 2, the detection device 1 includes the array substrate 2 (substrate 21), a sensor unit 10, a scan line drive circuit 15, a signal line selection circuit 16, a detection circuit 48, a control circuit 102, and a power supply circuit 103.

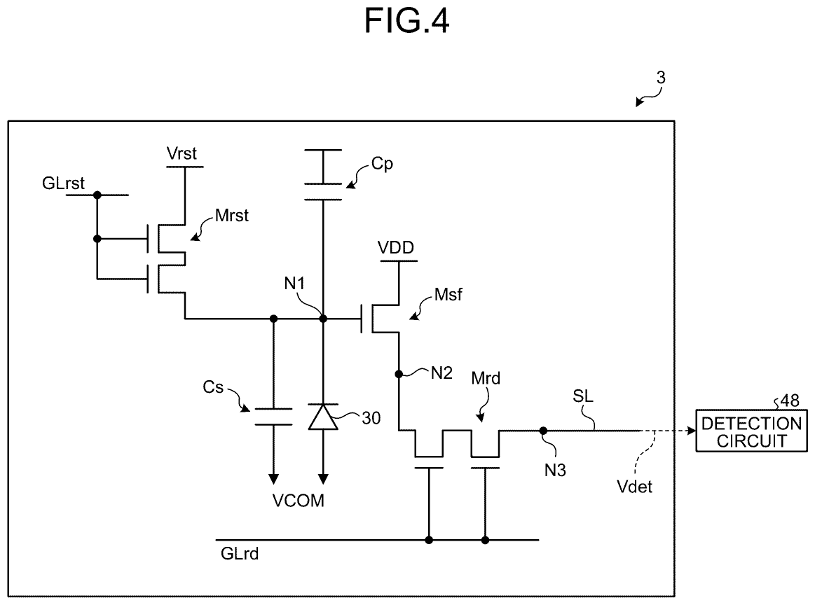

The substrate 21 is electrically coupled to a control substrate 101 through a wiring substrate 110. The wiring substrate 110 is, for example, a flexible printed circuit board or a rigid circuit board. The wiring substrate 110 is provided with the detection circuit 48. The control substrate 101 is provided with the control circuit 102 and the power supply circuit 103. The control circuit 102 is a field-programmable gate array (FPGA), for example. The control circuit 102 supplies control signals to the sensor unit 10, the scan line drive circuit 15, and the signal line selection circuit 16 to control operations of the sensor unit 10. The power supply circuit 103 supplies voltage signals including, for example, a power supply potential VDD and a reference potential VCOM (refer to FIG. 4) to the sensor unit 10, the scan line drive circuit 15, and the signal line selection circuit 16. In the present embodiment, the case is exemplified where the detection circuit 48 is disposed on the wiring substrate 110, but the present disclosure is not limited to this case. The detection circuit 48 may be disposed on the substrate 21.

The substrate 21 has the detection region AA and the peripheral region GA. The detection region AA and the peripheral region GA extend in planar directions parallel to the substrate 21. Each element (detection element 3) of the sensor unit 10 is provided in the detection region AA. The peripheral region GA is a region outside the detection region AA, and is a region not provided with the element (detection element 3). That is, the peripheral region GA is a region between the outer perimeter of the detection region AA and the ends of the substrate 21. The scan line drive circuit 15 and the signal line selection circuit 16 are provided in the peripheral region GA. The scan line drive circuit 15 is provided in a region extending along the second direction Dy in the peripheral region GA. The signal line selection circuit 16 is provided in a region extending along the first direction Dx in the peripheral region GA, and is provided between the sensor unit 10 and the detection circuit 48.

Each of the detection elements 3 of the sensor unit 10 is an optical sensor including the photodiode 30 as a sensor element. The photodiode 30 is a photoelectric conversion element, and outputs an electrical signal corresponding to light irradiating each of the photodiodes 30. More specifically, the photodiode 30 is a positive-intrinsic-negative (PIN) photodiode. The photodiode 30 may be an organic photodiode (OPD). The detection elements 3 are arranged in a matrix having a row-column configuration in the detection region AA. The photodiodes 30 included in the detection elements 3 perform the detection in response to gate drive signals (reset control signal RST and read control signal RD) supplied from the scan line drive circuit 15. Each of the photodiodes 30 outputs the electrical signal corresponding to the light irradiating the photodiode 30 as a detection signal Vdet to the signal line selection circuit 16. The detection device 1 detects the information on the living body based on the detection signals Vdet received from the photodiodes 30.

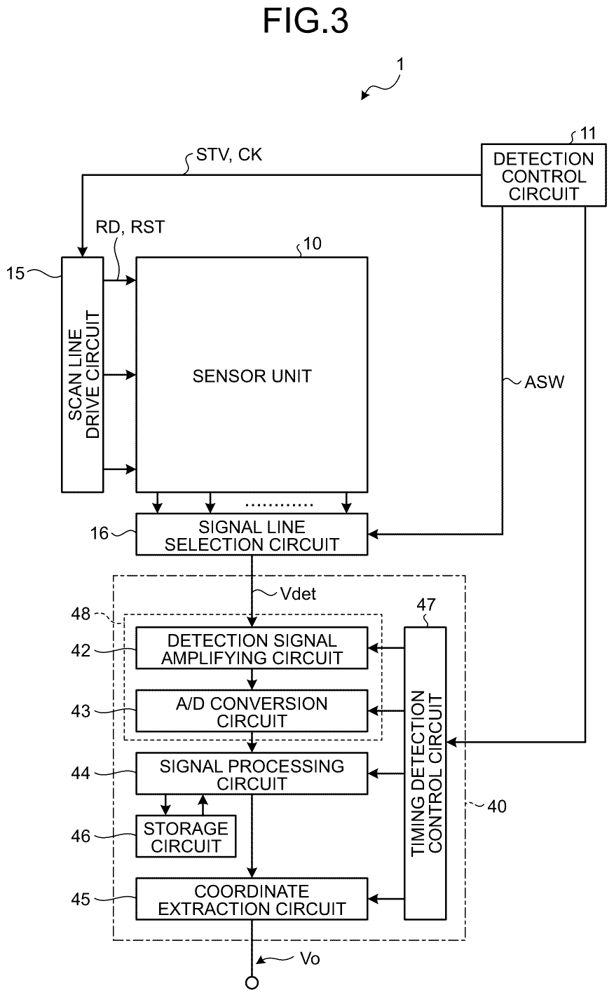

FIG. 3 is a block diagram illustrating a configuration example of the detection device according to the embodiment. As illustrated in FIG. 3, the detection device 1 further includes a detection control circuit 11 and a detector 40. The control circuit 102 includes one, some, or all functions of the detection control circuit 11. The control circuit 102 also includes one, some, or all functions of the detector 40 other than those of the detection circuit 48.

The detection control circuit 11 is a circuit that supplies respective control signals to the scan line drive circuit 15, the signal line selection circuit 16, and the detector 40 to control operations of these components. The detection control circuit 11 supplies various control signals including, for example, a start signal STV and a clock signal CK to the scan line drive circuit 15. The detection control circuit 11 also supplies various control signals including, for example, a selection signal ASW to the signal line selection circuit 16.

The scan line drive circuit 15 is a circuit that drives a plurality of scan lines (read control scan line GLrd and reset control scan line GLrst (refer to FIG. 4)) based on the various control signals. The scan line drive circuit 15 sequentially or simultaneously selects the scan lines, and supplies the gate drive signals (for example, the reset control signals RST and the read control signals RD) to the selected scan lines. Through this operation, the scan line drive circuit 15 selects the photodiodes 30 coupled to the scan lines.

The signal line selection circuit 16 is a switch circuit that sequentially or simultaneously selects a plurality of output signal lines SL (refer to FIG. 4). The signal line selection circuit 16 is a multiplexer, for example. The signal line selection circuit 16 couples the selected output signal lines SL to the detection circuit 48 based on the selection signal ASW supplied from the detection control circuit 11. Through this operation, the signal line selection circuit 16 outputs the detection signals Vdet of the photodiodes 30 to the detector 40.

The detector 40 includes the detection circuit 48, a signal processing circuit 44, a coordinate extraction circuit 45, a storage circuit 46, and a detection timing control circuit 47. The detection timing control circuit 47 controls the detection circuit 48, the signal processing circuit 44, and the coordinate extraction circuit 45 so as to operate in synchronization with one another based on a control signal supplied from the detection control circuit 11.

The detection circuit 48 is an analog front-end (AFE) circuit, for example. The detection circuit 48 is a signal processing circuit having functions of at least a detection signal amplifying circuit 42 and an analog-to-digital (A/D) conversion circuit 43. The detection signal amplifying circuit 42 amplifies the detection signal Vdet, and is an integration circuit, for example. The A/D conversion circuit 43 converts analog signals output from the detection signal amplifying circuit 42 into digital signals.

The signal processing circuit 44 is a logic circuit that detects a predetermined physical quantity received by the sensor unit 10 based on output signals of the detection circuit 48. The signal processing circuit 44 can detect the asperities on the surface of the finger Fg or a palm based on the signals from the detection circuit 48 when the finger Fg is in contact with or in proximity to a detection surface. The signal processing circuit 44 may detect the information on the living body based on the signals from the detection circuit 48. Examples of the information on the living body include the vascular image, the pulse waves, the pulsation, and a blood oxygen saturation level of the finger Fg or the palm.

The storage circuit 46 temporarily stores therein signals calculated by the signal processing circuit 44. The storage circuit 46 may be, for example, a random-access memory (RAM) or a register circuit.

The coordinate extraction circuit 45 is a logic circuit that obtains detected coordinates of the asperities on the surface of the finger Fg or the like when the contact or proximity of the finger Fg is detected by the signal processing circuit 44. The coordinate extraction circuit 45 is the logic circuit that also obtains detected coordinates of blood vessels of the finger Fg or the palm. The coordinate extraction circuit 45 combines the detection signals Vdet output from the respective detection elements 3 of the sensor unit 10 to generate two-dimensional information representing a shape of the asperities on the surface of the finger Fg or the like. The coordinate extraction circuit 45 may output the detection signals Vdet as sensor outputs Vo instead of calculating the detected coordinates.

The following describes a circuit configuration example of the detection device 1. FIG. 4 is a circuit diagram illustrating the detection element. As illustrated in FIG. 4, the detection element 3 includes the photodiode 30, a reset transistor Mrst, a read transistor Mrd, and a source follower transistor Msf. The reset transistor Mrst, the read transistor Mrd, and the source follower transistor Msf are provided correspondingly to each of the photodiodes 30. The reset transistor Mrst, the read transistor Mrd, and the source follower transistor Msf are each made up of an n-type thin-film transistor (TFT). However, each of the transistors is not limited thereto, and may be made up of a p-type TFT.

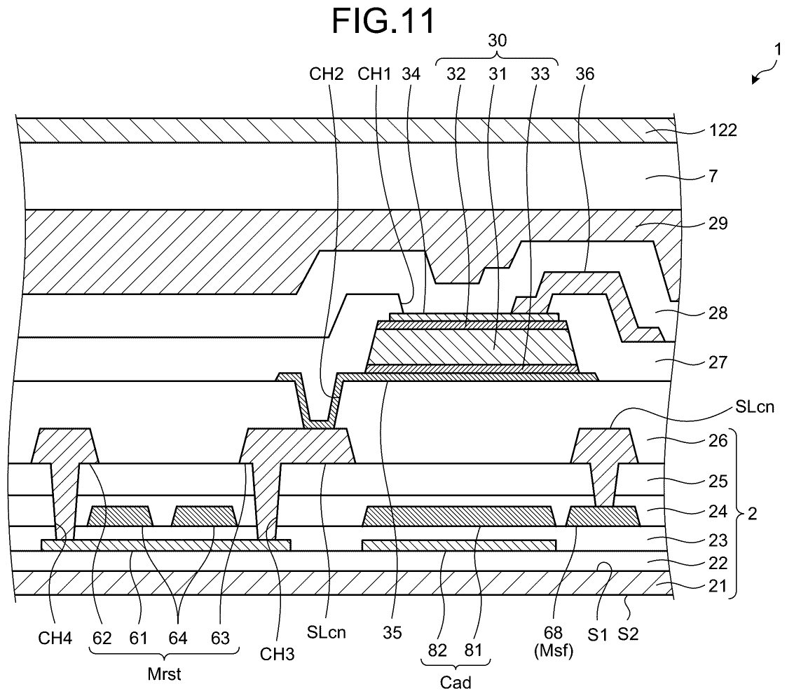

The reference potential VCOM is applied to the anode of the photodiode 30. The cathode of the photodiode 30 is coupled to a node N1. The node N1 is coupled to a capacitive element Cs, one of the source and the drain of the reset transistor Mrst, and the gate of the source follower transistor Msf. In addition, the node N1 has parasitic capacitance Cp. When light enters the photodiode 30, a signal (electric charge) output from the photodiode 30 is stored in the capacitive element Cs. The capacitive element Cs is, for example, capacitance generated between an upper electrode 34 and a lower electrode 35 that are coupled to the photodiode 30 (refer to FIG. 11). The parasitic capacitance Cp is capacitance added to the capacitive element Cs, and is capacitance generated among various types of wiring and electrodes provided on the array substrate 2.

The gate of the reset transistor Mrst is coupled to the reset control scan line GLrst. The other of the source and the drain of the reset transistor Mrst is supplied with a reset potential Vrst. When the reset transistor Mrst is turned on (into a conduction state) in response to the reset control signal RST, the potential of the node N1 is reset to the reset potential Vrst. The reference potential VCOM is lower than the reset potential Vrst, and the photodiode 30 is driven in a reverse bias state.

The source follower transistor Msf is coupled between a terminal supplied with the power supply potential VDD and the read transistor Mrd (node N2). The gate of the source follower transistor Msf is coupled to the node N1. The gate of the source follower transistor Msf is supplied with a signal (electric charge) generated by the photodiode 30. This operation causes the source follower transistor Msf to output a voltage signal corresponding to the signal (electric charge) generated by the photodiode 30 to the read transistor Mrd.

The read transistor Mrd is coupled between the source of the source follower transistor Msf (node N2) and a corresponding one of the output signal lines SL (node N3). The gates of the read transistor Mrd are coupled to the read control scan line GLrd. When the read transistor Mrd is turned on in response to the read control signal RD, the signal output from the source follower transistor Msf, that is, the voltage signal corresponding to the signal (electric charge) generated by the photodiode 30 is output as the detection signal Vdet to the output signal line SL.

In the example illustrated in FIG. 4, the reset transistor Mrst and the read transistor Mrd each have what is called a double-gate structure configured by coupling two transistors in series. However, the reset transistor Mrst and the read transistor Mrd are not limited to this structure, and may have a single-gate structure, or a multi-gate structure including three or more transistors coupled in series. The circuit of each of the detection elements 3 is not limited to the configuration including the three transistors of the reset transistor Mrst, the source follower transistor Msf, and the read transistor Mrd. The detection element 3 may include two transistors, or four or more transistors.

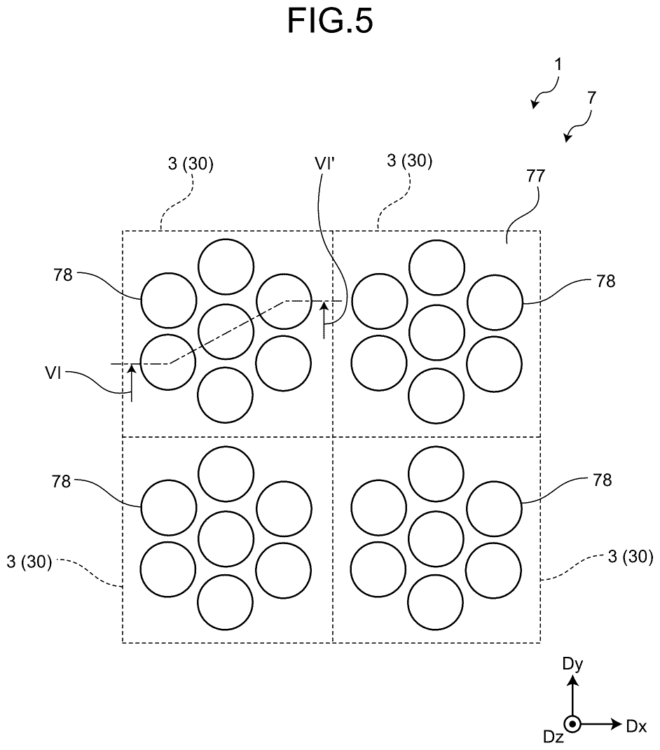

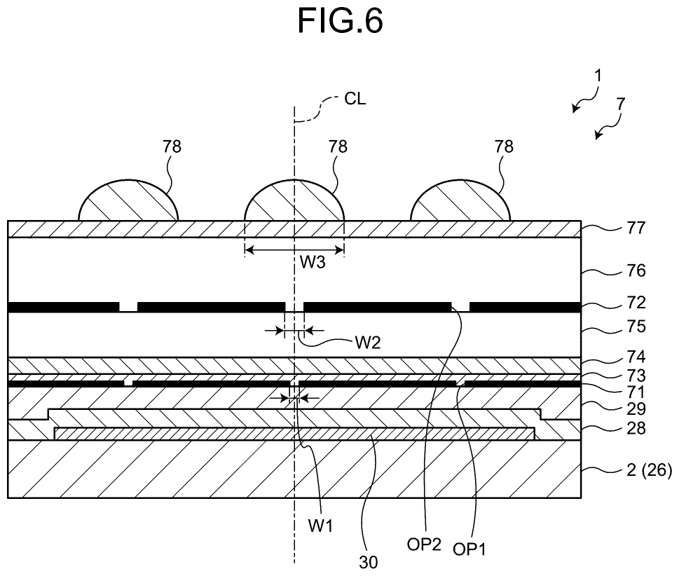

The following describes a detailed configuration of the detection elements 3 and the optical filter 7. FIG. 5 is a plan view illustrating an optical filter according to the embodiment; FIG. 6 is a sectional view along VI-VI′ of FIG. 5. FIG. 6 illustrates the configuration of the array substrate 2 in a simplified manner, and schematically illustrates insulating films 26 and 28, a protective film 29, and the photodiode 30. A detailed configuration of the array substrate 2 will be described later with reference to FIG. 11.

As illustrated in FIGS. 5 and 6, the optical filter 7 is provided so as to cover the detection elements 3 (photodiodes 30) arranged in a matrix having a row-column configuration. The optical filter 7 is an optical element that transmits, toward the photodiodes 30, components of the light L2 reflected by an object to be detected, such as the finger Fg, that travel in the third direction Dz, and blocks components of the light L2 that travel in oblique directions. The optical filter 7 is also called collimating apertures or a collimator.

The optical filter 7 includes a plurality of lenses 78 provided for each of the detection elements 3. More than one of the lenses 78 are arranged in a region overlapping each of the detection elements 3 (photodiodes 30). In the example illustrated in FIG. 5, each of the detection elements 3 is provided with seven of the lenses 78. The lenses 78 are arranged in a triangular lattice pattern. In more detail, in each of the detection elements 3, six of the lenses 78 are arranged in a regular hexagonal shape so as to surround one lens 78 located at the geometric center.

However, the number of the lenses 78 arranged in each of the detection elements 3 may be six or smaller, or eight or larger. The arrangement of the lenses 78 is also not limited to a triangular lattice pattern, and may be other patterns such as a matrix having a row-column configuration.

As illustrated in FIG. 6, the optical filter 7 includes a first light-blocking layer 71, a second light-blocking layer 72, a filter layer 73, a barrier layer 74, a first light-transmitting resin layer 75, a second light-transmitting resin layer 76, a buffer layer 77, and the lenses 78. In the present embodiment, the first light-blocking layer 71, the filter layer 73, the barrier layer 74, and the first light-transmitting resin layer 75, the second light-blocking layer 72, the second light-transmitting resin layer 76, the buffer layer 77, and the lenses 78 are stacked in this order on the protective film 29 covering the photodiode 30.

The lenses 78 are provided in direct contact with the top of the buffer layer 77. The lens 78 is a convex lens. An optical axis CL of the lens 78 is provided parallel to the third direction Dz and intersects the photodiode 30. In the example illustrated in FIG. 6, more than one of the lenses 78 are provided in a region overlapping each of the photodiodes 30, and the optical axes CL of the lenses 78 each intersect the photodiode 30.

The first light-blocking layer 71 is provided in direct contact with the top of the protective film 29 of the array substrate 2. In other words, the first light-blocking layer 71 is provided between the photodiode 30 and the lens 78 in the third direction Dz. The first light-blocking layer 71 is provided with a first opening OP1 in a region overlapping the photodiode 30. The first opening OP1 is formed in a region overlapping the optical axis CL of the lens 78. The first light-blocking layer 71 is formed, for example, of a metal material such as molybdenum (Mo).

The first light-blocking layer 71 can reflect components of the light L2 traveling in oblique directions other than the light L2 transmitted through the first opening OP1. Since the first light-blocking layer 71 is formed of a metal material, a diameter W1 (width in the first direction Dx) of the first opening OP1 can be accurately formed. Therefore, even when the arrangement pitch and the area (diameter W3) of the lens 78 are small, the first opening OP1 can be provided correspondingly to the lens 78.

The first light-blocking layer 71 is processed to form the first opening OP1 in a metal material deposited by sputtering or the like on the protective film 29 of the array substrate 2, and is different from a light-blocking layer formed by attaching what is called an external optical filter to the protective film 29 of the array substrate 2. Attaching the external optical filter onto the array substrate 2 is particularly difficult in matching the position of a small opening of a light-blocking layer corresponding to the first opening OP1 of the first light-blocking layer 71 of the present embodiment with the photodiode 30. In contrast, since the optical filter 7 of the present embodiment is directly formed on the protective film 29 of the array substrate 2, the first opening OP1 can be more accurately provided above the photodiode 30 than in the case of attaching the external optical filter.

In addition, unlike the second light-blocking layer 72 formed of a resin material to be described later, the first light-blocking layer 71 is formed of a metal material. Therefore, the first light-blocking layer 71 can be formed to be thinner than the second light-blocking layer 72 and can have the first opening OP1 that is smaller than a second opening OP2 formed in the second light-blocking layer 72. The thickness of the first light-blocking layer 71 is equal to or smaller than one tenth the thickness of the second light-blocking layer 72. As an example, the thickness of the first light-blocking layer 71 is equal to or larger than 0.055 μm, and is, for example, 0.065 μm, and the thickness of the second light-blocking layer is, for example, 1 μm. The first light-blocking layer 71 is formed to be much thinner than the second light-blocking layer 72.

The filter layer 73 is provided in direct contact with the top of the first light-blocking layer 71 so as to cover the first light-blocking layer 71 and the first opening OP1. The filter layer 73 is provided between the first light-blocking layer 71 and the first light-transmitting resin layer 75 in the third direction Dz. The filter layer 73 is a filter that blocks light in a predetermined wavelength band. The filter layer 73 is, for example, an infrared (IR) cut-off filter that is formed of a resin material colored in green and blocks infrared rays. With this configuration, the optical filter 7 can increase the detection sensitivity by allowing, for example, components of the light L2 in a wavelength band required for the fingerprint detection to enter the photodiode 30.

The barrier layer 74 is provided so as to cover the filter layer 73. The first light-transmitting resin layer 75 is provided on the barrier layer 74. The barrier layer 74 is provided between the group of the first light-blocking layer 71 and the filter layer 73 and the first light-transmitting resin layer 75 in the third direction Dz.

In the present embodiment, the barrier layer 74 is provided on the first light-blocking layer 71. Therefore, even when an easily ionizable metal material such as molybdenum (Mo) is used as the first light-blocking layer 71, the barrier layer 74 can reduce the diffusion of reactants (such as Mo-based ions) generated from the first light-blocking layer 71. More specifically, if the reactants (such as Mo-based ions) from the first light-blocking layer 71 diffuse and reach the first and the second light-transmitting resin layers 75 and 76, the reactants may react with the first and the second light-transmitting resin layers 75 and 76 to form a metal complex, which may cause discoloration. In the present embodiment, since the barrier layer 74 is provided, the first and the second light-transmitting resin layers 75 and 76 are prevented from being discolored by the diffusion of Mo-based ions, which can reduce the drop in light transmittance of the first and the second light-transmitting resin layers 75 and 76.

The barrier layer 74 is a light-transmitting resin material and is formed of an acrylic resin material, for example. The barrier layer 74 only needs to be a material that can reduce the transmittance of reactants. For example, the insulating film 26 used for the array substrate 2 or the same material as that of the protective film 29, that is, a hard coat film formed of an organic material, can be used. The thickness of the barrier layer 74 is, for example, from 2.0 μm to 3.0 μm. The thickness of the barrier layer 74 is larger than the thickness of the first light-blocking layer 71 and the filter layer 73, and smaller than the thickness of the first light-transmitting resin layer 75.

The first light-transmitting resin layer 75 is provided in direct contact with the top of the barrier layer 74. The first light-transmitting resin layer 75 is provided between the first light-blocking layer 71 and the second light-blocking layer 72 in the third direction Dz. The first and the second light-transmitting resin layers 75 and 76 are formed, for example, of a light-transmitting acrylic resin.

The second light-blocking layer 72 is provided in direct contact with the top of the first light-transmitting resin layer 75. The second light-blocking layer 72 is provided between the first light-blocking layer 71 and the lenses 78 in the third direction Dz. In the second light-blocking layer 72, the second opening OP2 is provided in a region overlapping the photodiode 30 and the first opening OP1. The second opening OP2 is formed in a region overlapping the optical axis CL of the lens 78. More preferably, the center of the second opening OP2 and the center of the first opening OP1 overlap the optical axis CL.

The second light-blocking layer 72 is formed, for example, of a resin material colored in black. As a result, the second light-blocking layer 72 serves as a light-absorbing layer that absorbs the components of the light L2 traveling in the oblique directions other than the light L2 passing through the second opening OP2. The second light-blocking layer 72 also absorbs light reflected by the first light-blocking layer 71. As a result, as compared with a configuration in which the second light-blocking layer 72 is formed of a metal material, the light reflected by the first light-blocking layer 71 can be restrained from traveling as stray light in the first light-transmitting resin layer 75 while being repeatedly reflected a plurality of times, and entering the other photodiodes 30. The second light-blocking layer 72 can also absorb outside light incident from between the adjacent lenses 78. As a result, as compared with the configuration in which the second light-blocking layer 72 is formed of a metal material, reflected light can be reduced in the second light-blocking layer 72. However, the second light-blocking layer 72 is not limited to the example of being formed of a resin material colored in black, and may be formed of a metal material having blackened surfaces.

The second light-transmitting resin layer 76 is provided in direct contact with the top of the second light-blocking layer 72. The second light-transmitting resin layer 76 is provided between the second light-blocking layer 72 and the group of the buffer layer 77 and the lenses 78.

The same material as that of the first light-transmitting resin layer 75 is used for the second light-transmitting resin layer 76, and thus, the refractive index of the second light-transmitting resin layer 76 is substantially equal to the refractive index of the first light-transmitting resin layer 75. As a result, the light L2 can be restrained from being reflected on an interface between the first light-transmitting resin layer 75 and the second light-transmitting resin layer 76 in the second opening OP2. However, the first light-transmitting resin layer 75 and the second light-transmitting resin layer 76 are not limited to this configuration, and may be formed of different materials, and the refractive index of the first light-transmitting resin layer 75 may differ from that of the second light-transmitting resin layer 76.

In the present embodiment, the diameter decreases in the order of the diameter W3 (width in the first direction Dx) of the lens 78, a diameter W2 (width in the first direction Dx) of the second opening OP2, and the diameter W1 (width in the first direction Dx) of the first opening OP1. The diameter W3 of the lens 78, the diameter W2 of the second opening OP2, and the diameter W1 of the first opening OP1 are each smaller than the width of the photodiode 30. The diameter W2 of the second opening OP2 and the diameter W1 of the first opening OP1 are appropriately set according to the shape (diameter W3, curvature, and so forth) of the lens 78 and the distance between the lens 78 and the photodiode 30.

The thickness of each of the first light-transmitting resin layer 75 and the second light-transmitting resin layer 76 is substantially 10 μm to 30 μm. In the example illustrated in FIG. 6, the first light-transmitting resin layer 75 is formed to have a smaller thickness than the second light-transmitting resin layer 76. However, the thickness of the first light-transmitting resin layer 75 is not limited to this example, and may be equal to the thickness of the second light-transmitting resin layer 76. Alternatively, the first light-transmitting resin layer 75 may be formed to have a larger thickness than the second light-transmitting resin layer 76.

The buffer layer 77 is provided in direct contact with the top of the second light-transmitting resin layer 76. The lens 78 is provided in direct contact with the top of the buffer layer 77. In other words, the second light-transmitting resin layer 76 and the buffer layer 77 are stacked between the second light-blocking layer 72 and the lens 78. The thickness of the buffer layer 77 is, for example, substantially 1.0 μm to 2.0 μm. The thickness of the buffer layer 77 is smaller than the thickness of each of the first and the second light-transmitting resin layers 75 and 76.

The buffer layer 77 is formed of a light-transmitting resin material that contains a material different from that of the second light-transmitting resin layer 76. In more detail, the buffer layer 77 is formed containing a light-transmitting acrylic resin and a surfactant of the same family as a material used for the lens 78. The buffer layer 77 contains, for example, a fluorosurfactant or a Si surfactant. As a result, when the resin material of the lens 78 is applied and formed in the manufacturing process of the detection device 1, the wettability between the resin material of the lens 78 and the buffer layer 77 is improved compared with a case where the resin material of the lens 78 is directly applied and formed on the second light-transmitting resin layer 76 without providing the buffer layer 77. As a result, the shape of the lens 78 formed on the buffer layer 77 is stabilized and the radius of curvature of the lens 78 is made constant. That is, in one lens 78, when the lens is divided into a plurality of pieces along an arc in the sectional structure, the variation in radius of curvature of each of the divided arcs can be reduced.

With the configuration described above, the light L2 traveling in the third direction Dz among rays of the light L2 reflected by the object to be detected such as the finger Fg is condensed by the lens 78 as designed, and passes through the second opening OP2 and the first opening OP1 well to enter the photodiode 30. The light L2 tilted at a predetermined angle with respect to the third direction Dz is blocked by the first light-blocking layer 71 and the second light-blocking layer 72. Thus, the detection device 1 of the present embodiment can improve detection accuracy compared with the case where the buffer layer 77 is not included and the lens 78 is formed on the second light-transmitting resin layer 76.

As described above, the optical filter 7 is formed directly on the array substrate 2 by applying processes such as patterning. That is, the first light-blocking layer 71 of the optical filter 7 is provided in direct contact with the top of the protective film 29, and no member such as an adhesive layer is provided between the first light-blocking layer 71 and the protective film 29. The optical filter 7 is, however, not limited to this configuration, and may be what is called an external optical filter attached to the protective film 29 of the array substrate 2 with an adhesive layer interposed therebetween.

The optical filter 7 is also not limited to the configuration including the first light-blocking layer 71 and the second light-blocking layer 72, and may be formed including only one light-blocking layer. For example, in FIG. 6, the second light-blocking layer 72 and the second light-transmitting resin layer 76 may be eliminated, and the buffer layer 77 and the lens 78 may be provided on the first light-transmitting resin layer 75. Although the filter layer 73 is provided between the first light-blocking layer 71 and the first light-transmitting resin layer 75, the position of the filter layer 73 is not limited to this position. The position of the filter layer 73 can be changed as appropriate depending on the characteristics required for the optical filter 7 and the manufacturing process. The optical filter 7 is not limited to the configuration in which a light-blocking layer and a light-transmitting resin layer are stacked. For example, the optical filter 7 may have a light guide column structure. That is, the optical filter 7 may have a configuration including a non-light-transmitting member formed of a black resin material and a plurality of light-transmitting regions (light guide columns) formed into columnar shapes penetrating upper and lower surfaces of the non-light-transmitting member.

### Example

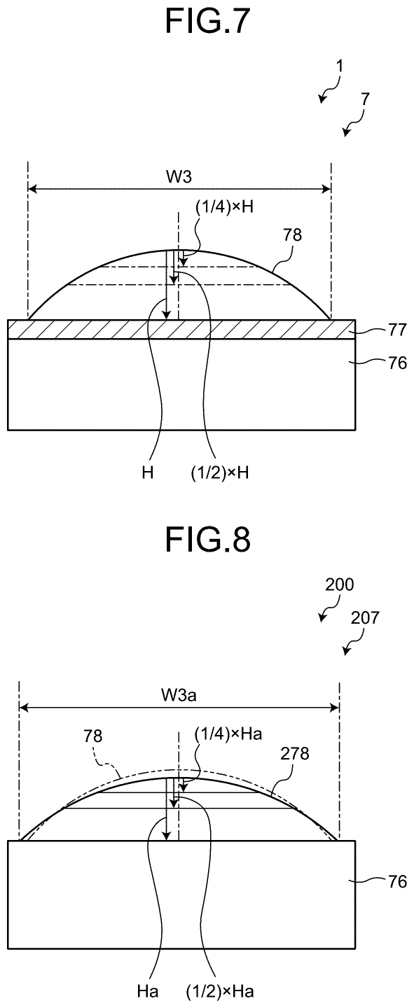

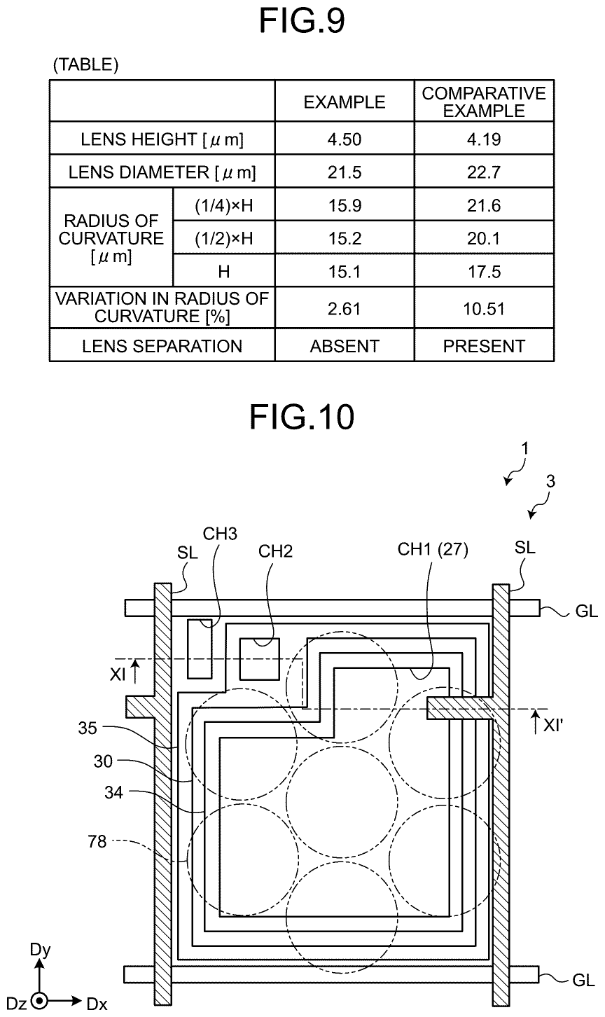

FIG. 7 is an explanatory view schematically illustrating a sectional configuration of the lens according to an example. FIG. 8 is an explanatory view schematically illustrating a sectional configuration of the lens according to a comparative example. FIG. 9 is a table illustrating measurement results of the lens according to the example and the lens structure according to the comparative example. FIG. 8 illustrates the lens 78 with a long dashed double-short dashed line in order to facilitate understanding.

In the example illustrated in FIG. 7, the buffer layer 77 is provided on the second light-transmitting resin layer 76, and the lens 78 is formed on the buffer layer 77. In a detection device 200 and an optical filter 207 of the comparative example illustrated in FIG. 8, the buffer layer 77 is not provided and a lens 278 is formed on the second light-transmitting resin layer 76.

As illustrated in FIG. 9, heights H and Ha, diameters W3 and W3a, radii of curvature, variations in the radii of curvature, and presence or absence of lens separation were measured for the lens 78 of the example and the lens 278 of the comparative example. The radius of curvature was measured for each region of the lenses 78 and 278. Specifically, the radii of curvature of the arcs of the lenses 78 and 278 in regions from the tops to ¼ of the heights H and Ha, the radii of curvature of the arcs of the lenses 78 and 278 in regions from the tops to ½ of the heights H and Ha, and the radii of curvature of the arcs of lenses 78 and 278 in regions from the tops to 1/1 of the heights H and Ha (the entire ranges) were obtained.

The variation in the radius of curvature illustrated in FIG. 9 was calculated using Expression (1) below, where Rmax denotes the maximum radius of curvature and Rmin denotes the minimum radius of curvature among the radii of curvature of the three regions described above for each of the example and the comparative example.

((Rmax−Rmin)/(Rmax+Rmin))×100(%) (1)

As illustrated in FIGS. 7 to 9, the height H of the lens 78 of the example is made larger than the height Ha of the lens 278 of the comparison example, and the diameter W3 of the lens 78 of the example is smaller than the diameter W3a of the lens 278 of the comparison example.

The radius of curvature of the lens 78 of the example is made to have a substantially constant value in each of regions (¼)×H, (½)×H, and H. The variation in radius of curvature of the lens 78 of the example calculated by Expression (1) is restrained to a small value of 2.61%.

The lens 278 of the comparative example is made to have a larger radius of curvature than the lens 78 of the example in each of the regions (¼)×H, (½)×H, and H. The radius of curvature of the lens 278 of the comparative example is made to have a variation in each of the regions (¼)×H, (½)×H, and H. Specifically, the lens 278 of the comparative example has a larger radius of curvature as the position is closer to the top (for example, in the region up to the height (¼)×H) and a smaller radius of curvature as the position is farther from the top (for example, in the region up to the height H). The variation in radius of curvature of the lens 278 of the comparative example calculated by Expression (1) is 10.51%.

The term “lens separation” illustrated in FIG. 9 denotes the presence or absence of one or some of the lenses 78 or 278 provided in the detection region AA that were separated from the buffer layer 77 (second light-transmitting resin layer 76 in the comparative example), and the lenses 78 or 278 dropped off and were not formed. As illustrated in FIG. 9, in the example, no lens separation occurred and all the lenses 78 were well formed. In contrast, in the comparative example, the lens separation occurred and some of the lenses 278 dropped off and were not formed.

As described above, it has been demonstrated that providing the buffer layer 77 for the lens 78 according to the example improves the wettability between the lens 78 and the buffer layer 77 and improves the uniformity of the curvature compared with the comparative example. That is, in the-sectional structure of the lens 78 according to the example, the variation in the radius of curvature of each of the portions divided along the arc is reduced. Furthermore, it has been demonstrated that the lens separation of the lens 78 according to the example is also restrained.

The following describes a configuration example of the photodiode 30 and the array substrate 2. FIG. 10 is a plan view schematically illustrating the photodiode of the detection device according to the embodiment. FIG. 11 is a sectional view along XI-XI′ of FIG. 10. FIG. 10 illustrates the lenses 78 overlapping the photodiode 30 with long dashed double-short dashed lines in order to facilitate viewing of the drawing. While FIG. 11 illustrates a sectional configuration of the reset transistor Mrst among the three transistors included in the detection element 3, each of the source follower transistor Msf and the read transistor Mrd also has a sectional configuration similar to that of the reset transistor Mrst.

As illustrated in FIG. 10, a plurality of scan lines GL each extend in the first direction Dx and are arranged to be lined up in the second direction Dy. The output signal lines SL each extend in the second direction Dy and are arranged to be lined up in the first direction Dx. One detention element 3 (photodiode 30) is formed in a region surrounded by two of the scan lines GL and two of the output signal lines SL. The scan line GL illustrated in FIG. 10 is either one of the read control scan line GLrd and the reset control scan line GLrst (refer to FIG. 4).

As illustrated in FIG. 11, the photodiode 30 is provided on the array substrate 2, that is, on a first principal surface S1 side of the substrate 21. The substrate 21 is an insulating substrate. A glass substrate of, for example, quartz or alkali-free glass is used as the substrate 21. The substrate 21 has the first principal surface S1 and a second principal surface S2 opposite the first principal surface S1. The various transistors including the reset transistor Mrst, the various types of wiring (scan lines and signal lines), and insulating films are provided on the first principal surface S1 of the substrate 21 to form the array substrate 2.

An undercoat film 22 is provided on the first principal surface S1 of the substrate 21. The undercoat film 22, insulating films 23, 24, and 25, and insulating films 27 and 28 are inorganic insulating films, and are formed of, for example, silicon oxide (SiO₂) or silicon nitride (SiN).

A semiconductor layer 61 is provided on the undercoat film 22. For example, polysilicon is used as the semiconductor layer 61. The semiconductor layer 61 is, however, not limited thereto, and may be formed of, for example, a microcrystalline oxide semiconductor, an amorphous oxide semiconductor, or low-temperature polycrystalline silicon (LTPS).

The insulating film 23 is provided on the undercoat film 22 so as to cover the semiconductor layer 61. Gate electrodes 64 are provided on the insulating film 23. A gate electrode 68 of the source follower transistor Msf in the same layer as the gate electrodes 64 is also provided on the insulating film 23. The scan lines GL (reset control scan line GLrst and read control scan line GLrd) are also provided in the same layer as the gate electrodes 64. The insulating film 24 is provided on the insulating film 23 so as to cover the gate electrodes 64.

As illustrated in FIG. 11, the reset transistor Mrst has a top-gate structure in which the gate electrodes 64 are provided above the semiconductor layer 61. However, in the detection device 1, the reset transistor Mrst may have a bottom-gate structure in which the gate electrodes 64 are provided below the semiconductor layer 61, or a dual-gate structure in which the gate electrodes 64 are provided above and below the semiconductor layer 61.

The insulating films 24 and 25 are provided on the insulating film 23 so as to cover the gate electrodes 64. A source electrode 62 and a drain electrode 63 are provided on the insulating film 25. The source electrode 62 is coupled to a source region of the semiconductor layer 61 through a contact hole CH4 penetrating the insulating films 23, 24, and 25. The drain electrode 63 is coupled to a drain region of the semiconductor layer 61 through a contact hole CH3 penetrating the insulating films 23, 24, and 25. The source electrode 62 and the drain electrode 63 are formed of, for example, a multilayered film of Ti—Al—Ti layers or Ti—Al layers that has a multilayered structure of titanium and aluminum.

The output signal line SL and coupling wiring SLcn are provided in the same layer as the source electrode 62 and drain electrode 63. The coupling wiring SLcn of the detection element 3 is coupled to the gate electrode 68 of the source follower transistor Msf through a contact hole penetrating the insulating films 24 and 25.

A first electrode 81 and a second electrode 82 are provided in regions overlapping the photodiode 30. Capacitance Cad is generated between the first electrode 81 and the second electrode 82. The capacitance Cad is capacitance added to the photodiode 30 and is coupled in parallel to the capacitive element Cs illustrated in FIG. 4. The first and the second electrodes 81 and 82 are provided using two of the layers forming the transistors (for example, the reset transistor Mrst). In the present embodiment, the second electrode 82 is located in the same layer as the semiconductor layer 61, and is formed of the same material as the semiconductor layer 61. The first electrode 81 is located in the same layer as the gate electrodes 64, and is formed of the same material as the gate electrodes 64.

The insulating film 26 is provided on the insulating film 25 so as to cover the various transistors such as the reset transistor Mrst. The insulating film 26 is formed of an organic material such as a photosensitive acrylic. The insulating film 26 is thicker than the insulating film 25. The insulating film 26 has a better step covering property than that of inorganic insulating materials, and can planarize steps formed by the various transistors and the various types of wiring.

The photodiode 30 is provided above the insulating film 26. Specifically, the lower electrode 35 is provided on the insulating film 26, and is electrically coupled to the coupling wiring SLcn through a contact hole CH2. The photodiode 30 is coupled to the lower electrode 35. The lower electrode 35 can employ, for example, a multilayered structure of titanium (Ti) and titanium nitride (TiN). Since the lower electrode 35 is provided between the substrate 21 and semiconductor layers of the photodiode 30, the lower electrode 35 serves as a light-blocking layer, and can restrain light from entering the photodiode 30 from the second principal surface S2 side of the substrate 21.

The photodiode 30 is configured with the semiconductor layers having a photovoltaic effect. Specifically, the semiconductor layers of the photodiode 30 include an i-type semiconductor layer 31, a p-type semiconductor layer 32, and an n-type semiconductor layer 33. The i-type semiconductor layer 31, the p-type semiconductor layer 32, and the n-type semiconductor layer 33 are formed of amorphous silicon (a-Si), for example. The material of the semiconductor layers is not limited thereto, and may be, for example, polysilicon or microcrystalline silicon.

The a-Si of the p-type semiconductor layer 32 is doped with impurities to form a p+ region. The a-Si of the n-type semiconductor layer 33 is doped with impurities to form an n+ region. The i-type semiconductor layer 31 is, for example, a non-doped intrinsic semiconductor, and has lower conductivity than the p-type semiconductor layer 32 and the n-type semiconductor layer 33.

The i-type semiconductor layer 31 is provided between the n-type semiconductor layer 33 and the p-type semiconductor layer 32 in a direction orthogonal to a surface of the substrate 21 (in the third direction Dz). In the present embodiment, the n-type semiconductor layer 33, the i-type semiconductor layer 31, and the p-type semiconductor layer 32 are stacked in this order on the lower electrode 35. In the present embodiment, the upper electrode 34 is an anode electrode of the photodiode 30, and the lower electrode 35 is a cathode electrode of the photodiode 30.

The lower electrode 35 is provided so as to extend to the outside of the photodiode 30, that is, to a region that does not overlap the n-type semiconductor layer 33, the i-type semiconductor layer 31, and the p-type semiconductor layer 32. The lower electrode 35 is electrically coupled to the coupling wiring SLcn, the reset transistor Mrst, and the source follower transistor Msf through the contact hole CH2 provided in the insulating film 26.

The upper electrode 34 is provided on the p-type semiconductor layer 32. The upper electrode 34 is formed of, for example, a light-transmitting conductive material such as indium tin oxide (ITO). The insulating film 27 is provided on the insulating film 26 so as to cover the photodiode 30 and the upper electrode 34. A contact hole CH1 (opening) is provided in a region of the insulating film 27 overlapping the upper electrode 34.

Coupling wiring 36 is provided on the insulating film 27, and is electrically coupled to the upper electrode 34 through the contact hole CH1 (opening). The p-type semiconductor layer 32 is supplied with the reference potential VCOM (refer to FIG. 4) through the coupling wiring 36 and the upper electrode 34.

The insulating film 28 is provided on the insulating film 27 so as to cover the upper electrode 34 and the coupling wiring 36. The insulating film 28 is provided as a protective layer for restraining water from entering the photodiode 30. The protective film 29 is further provided on the insulating film 28. The protective film 29 is a hard coat film (organic protective film) formed of an organic material. The protective film 29 planarizes steps on a surface of the insulating film 28 formed by the photodiode 30 and the coupling wiring 36.

The optical filter 7 is provided on the protective film 29. The optical filter 7 is provided directly on the protective film 29 with no adhesive layer interposed therebetween. The cover member 122 is provided on the optical filter 7. The cover member 122 is attached by the adhesive layer 125 (refer to FIG. 1) to the optical filter 7. The adhesive layer 125 is a light-transmitting optical clear adhesive (OCA) sheet, for example.

The configuration of the photodiode 30 illustrated in FIGS. 10 and 11 is merely exemplary, and can be changed as appropriate. For example, the stacking order of the photodiode 30 may be reversed; that is, the p-type semiconductor layer 32, the i-type semiconductor layer 31, and the n-type semiconductor layer 33 may be stacked in this order on the lower electrode 35.

While the preferred embodiment of the present disclosure has been described above, the present disclosure is not limited to the embodiment described above. The content disclosed in the embodiment is merely an example, and can be variously modified within the scope not departing from the gist of the present disclosure. Any modifications appropriately made within the scope not departing from the gist of the present disclosure also naturally belong to the technical scope of the present disclosure. At least one of various omissions, substitutions, and changes of the components can be made without departing from the gist of the embodiment and the modifications described above.

What is claimed is:

1. A detection device comprising:
a substrate;
a photodiode provided on the substrate;
a lens provided so as to overlap the photodiode;
a light-blocking layer that is provided between the photodiode and the lens, and is provided with an opening in a region overlapping the photodiode; and
a light-transmitting resin layer and a buffer layer that are stacked between the light-blocking layer and the lens, wherein
the lens is provided in direct contact with a top of the buffer layer.

2. The detection device according to claim 1, wherein the buffer layer is formed of a resin material containing a material different from that of the light-transmitting resin layer.

3. The detection device according to claim 1, wherein the buffer layer is formed of a resin material containing a surfactant of the same family as a material used for the lens.

4. The detection device according to claim 1, wherein the buffer layer has a smaller thickness than that of the light-transmitting resin layer.

5. The detection device according to claim 1, comprising a barrier layer that is provided between the light-blocking layer and the light-transmitting resin layer and is formed of an acrylic resin.

6. The detection device according to claim 5, comprising a filter layer that is provided so as to cover the light-blocking layer and the opening and is configured to block light in a predetermined wavelength band, wherein
the barrier layer is provided so as to cover the filter layer, and
the light-transmitting resin layer is provided above the barrier layer.

7. The detection device according to claim 1, comprising an organic protective film covering the photodiode, wherein
the light-blocking layer comprises:
a first light-blocking layer that is provided above the organic protective film and is provided with a first opening in a region overlapping the photodiode; and
a second light-blocking layer that is provided between the first light-blocking layer and the lens and is provided with a second opening in a region overlapping the photodiode and the first opening, and
the light-transmitting resin layer comprises:
a first light-transmitting resin layer provided between the first light-blocking layer and the second light-blocking layer; and
a second light-transmitting resin layer provided between the second light-blocking layer and the buffer layer.

8. The detection device according to claim 1, comprising a plurality of the lenses, wherein
the lenses are provided in a region overlapping the one photodiode.
